(19) United States
(12) Patent Application Publication
(10) Pub. No.: US 2014/0166072 A1
(43) Pub. Date: Jun. 19, 2014

(54) PHOTOVOLTAIC ASSEMBLY

(71) Applicant: Roland Schilling, Gemmingen (DE)

(72) Inventor: Roland Schilling, Gemmingen (DE)

(21) Appl. No.: 13/982,581

(22) PCT Filed: Jan. 27, 2012
(86) PCT No.: PCT/EP2012/051314

§ 371 Date: Dec. 6, 2013

(30) Foreign Application Priority Data
Jan. 31, 2011 (DE) 10 2011 000 418.1

(51) Int. Cl. H01L 27/142

(52) U.S. Cl. CPC H01L 27/1421
USPC 136/246

(57) ABSTRACT

The invention relates to a photovoltaic assembly (10) comprising a support substrate (12) consisting of silicon, a solar cell (26), in particular a solar concentrator cell, said cell having a first and a second solar cell contact (28, 30) and being connected to the upper face (38) of the support substrate (12) by means of the first solar cell contact (28), a pn-junction (46) that is integrated into the support substrate (12) in order to form a protective diode (14) comprising a first protective diode contact (16) and a second protective diode contact (20), said diodes being connected in anti-parallel to the solar cell (26). In order to design the contacts of the protective diode with as large a surface area as possible and to permit a simple contacting of the solar cell, the first and second protective diode contact (16, 20) form a first and second surface area (18, 22) respectively of the upper face (38) of the support substrate (12).

The invention relates to a photovoltaic assembly comprising a carrier substrate of silicon, a solar cell comprising a first and a second solar cell contact, in particular a concentrator solar cell, which solar cell is connected to the first solar cell contact on an top side of the carrier substrate, a pn junction integrated in the carrier substrate for forming a protective diode with a first protective diode contact and with a second protective diode contact connected in antiparallel to the solar cell, whereby the first and the second protective diode contact respectively form a first and a second surface area of the top side of the carrier substrate.

A photovoltaic assembly known from DE-A-10 2008 055 475 comprises interconnected solar cells that emanate from a carrier substrate of silicon in such a manner that each one of the solar cells is received at least sectionally by the carrier substrate surrounding the solar cell at least like a frame, and that the solar cells are connected via the carrier substrate or in an area not covered by the carrier substrate. Furthermore, it is provided that a pn junction is formed in the carrier substrate for forming a protective diode connected in antiparallel to the solar cell. The protective diode is connected on the one hand to a first solar cell contact (rear side contact) and on the other hand via a feedthrough to a second solar cell contact (front side contact). More information about designing the pn junction and the protective diode cannot be gathered from DE-A-10 2008 055 475.

A photovoltaic assembly of the initially cited type can be gathered from DE-T-689 23 061. The solar cell lies directly on the substrate, so that a good dissipation of heat is not possible.

In a photovoltaic assembly according to U.S. Pat. No. 7,592,536 bypass diodes are arranged on a plate bar that emanate from a cooling body.

A lightweight solar module is described in DE-A-101 21 895. Here, several solar cells are arranged on a substrate.

A solar cell with an integrated protective diode present on the front side is known from DE-A-100 56 214.

DE-A-10 208 055 475 describes an arrangement of interconnected concentrator solar cells emanating from a receiver via which the solar cells are connected.

The subject matter of DE-A-10 210 027 747 is a photovoltaic module with solar cells contacted on the back side.

In a solar cell arrangement in accordance with DE-A-10 2004 044 061 a solar cell is connected to a discrete protective diode that comprises in addition to a front contact and a rear contact a third contact at a distance to the front contact and electrically connected via a pn junction.

A solar module in integrated thin-layer technology is described in EP-B-0 933 818.

A protective diode is arranged on the back side of a solar cell in accordance with US-A-2004/0089339.

Solar cells that are connected serially on the front side are known from US-A-2010/0089435.

The present invention has the basic problem of further developing a photovoltaic assembly of the initially cited type in such a manner that the contacts of the protective diode are constructed to have as large a surface as possible for forming a heat sink and that a simple contacting of the solar cell is made possible. Also, in particular an application for concentrator solar cells should be possible.

The problem is solved in accordance with the invention substantially in that the top side of the carrier substrate is provided with an insulation layer, whereby a first contact window for the first protective diode contact is formed in the first surface area and in the second surface area a second contact window for the second protective diode contact is formed, that the first surface area comprises a first metallization conductively connected to the first contact window and the second surface area comprises a second metallization connected to the second contact window, that the first and the second metallizations are constructed as the first and the second metallization surfaces, and that the solar cell lies with the first solar cell contact in a planar manner on the first metallization surface and that the second solar cell contact is connected via connectors to the second metallization surface.

Based on the teaching in accordance with the invention, the solar cell lies all over or substantially all over on a metallization forming a heat sink, which metallization is connected for its part in an electrically conductive manner to one of the contacts of the protective diode. Therefore, the solar cell with its first solar cell contact as back side contact runs on the first surface area whereas the second solar cell contact can be connected as the front side contact to the second surface area, i.e., to the second protective diode contact.

In order to obtain the largest possible contact surface for the first and the second solar cell contacts, the invention provides that the top side of the carrier substrate is provided with an insulation layer such as silicon oxide, whereby a first contact window for the first protective diode contact is constructed in the first surface area and in the second surface area the second contact window for the second protective diode contact is constructed.

It is provided for a further improvement of the contacting and heat dissipation that the first surface area comprises a first metallization conductively connected to the first contact window and that the second surface area comprises a second metallization connected to the second contact window.

The first and the second metallizations are constructed as first and second metallization surfaces preferably located in a plane, whereby the solar cell lies with its first solar cell contact all over on the first metallization surface and is connected via connectors to the second metallization surface.

An area of the first metallization surface that receives the solar cell can preferably be enclosed at least in areas by the second metallization surface, whereby the pn junction is preferably constructed in a U-shape in the carrier substrate and surrounds a surface that corresponds substantially to a contact surface of the first solar cell contact.

Due to the large-surface formation on the one hand of the solar cell contacts and on the other hand of the protective diode contacts as surface areas of the carrier substrate, it is ensured that the carrier substrate and in particular the metallization surfaces are at the same time also heat sinks for the protective diode and the solar cell.

In another preferred embodiment a back side of the carrier substrate can comprise a back-side metallization in order, for example, to make a soldered connection to another carrier possible.

The solar cell is preferably constructed as a concentrator solar cell, whereby it can be covered by a secondary optical lens.

A feature of the inventor that should be emphasized is distinguished in that the first protective diode contact in the form of an n- or p-conductive zone as the first surface area diffuses into the top side of the p- or n-conductive carrier substrate, consisting especially of silicon, which top side forms the second surface area, or this contact is implanted and has a U-shaped course.

It is provided in particular that the zone having a U-shaped course, that is, e.g., an n-conductive zone, if the substrate is p-conductive, surrounds the solar cell, whereby an edge of the substrate extends along the transverse shank and the bordering edges extend at least in sections, preferably completely along the side shanks of the corresponding zone.

The n-conductive zone is then connected in an electrically conductive manner to the first metallizing surface on which the solar cell is arranged. Thus, a connecting of the protective diode to the solar cell with the simultaneous formation of a heat sink is possible in a simple manner.

In another embodiment to be emphasized it is provided that the solar cell is covered by an optical element, in particular is adhered to the latter.

Furthermore, the front side of the carrier substrate can be covered and its circumferential sides can be covered at least in sections by a jacketing that is recessed above the solar cell so that the solar cell can be loaded with radiation.

Furthermore, the jacketing should have a recess such as a window above the first and the second metallization in order to make possible a connecting of the solar cell. In contrast thereto, the back side of the substrate should be jacket-free in order to make a dissipation of heat downward to a heat sink possible.

In other words, the photovoltaic assembly can be adhered to an optical element such as a lens, glass body, or cover glass. This optical element acts as a light trap or entrance window for the solar cell. Furthermore, the photovoltaic assembly can be surrounded by a suitable housing mass, in particular consisting of heat-resistant plastic, by injection molding or molding, which plastic is recessed in the area of the solar cell and if an optical element is present this element extends through the plastic. Furthermore, openings are provided in the area of the metallization, whereby an opening such as a contact window is let in in the area of each metallization. The openings serve for the electrical connecting of the assembly.

It is provided with special preference that the first and the second metallization are separated in a top view onto the carrier substrate by a section of the insulation layer running in a strip, that the section consists of a middle area of the substrate surrounding the middle section with transverse shanks and side shanks and extending parallel to or approximately parallel to the n- or p-conductive zone running in a U-shape and of outer sections running from the free ends of the side shanks and parallel to the transverse shank, and that the solar cell is surrounded by the middle section.

The invention furthermore provides that a connector, preferably two connectors emanate at least from opposite sides of the second solar cell contact that extend over one of the side shanks of the strip-shaped section of the insulation.

Other details, advantages and features of the invention result not only from the claims, the features to be gathered from them by themselves and/or in combination, but also from the following description of preferred exemplary embodiments to be gathered from the drawings.

In the drawings:

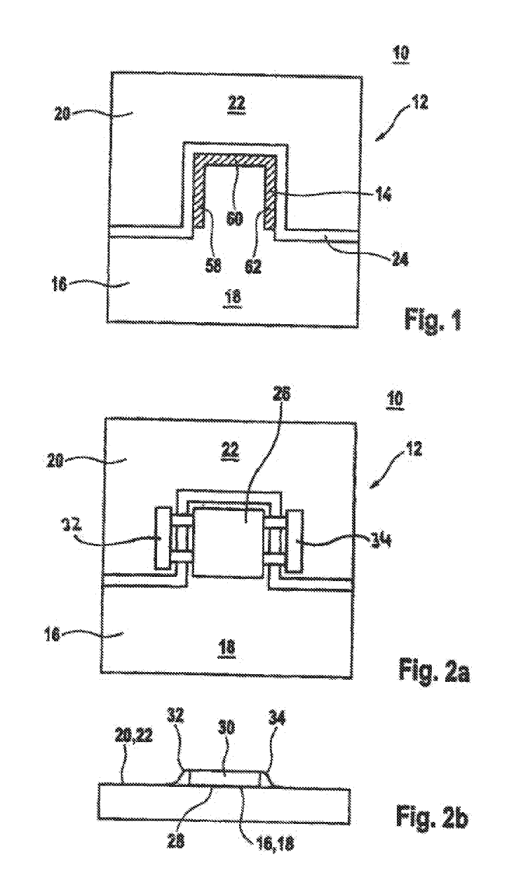

FIG. 1 shows a top view of a carrier substrate with integrated protective diode and first and second protective diode contacts on the surface side,

FIG. 2a shows a top view of the photovoltaic assembly and contacted solar cell,

FIG. 2b shows a lateral view of the carrier substrate with integrated protective diode and contacted solar cell,

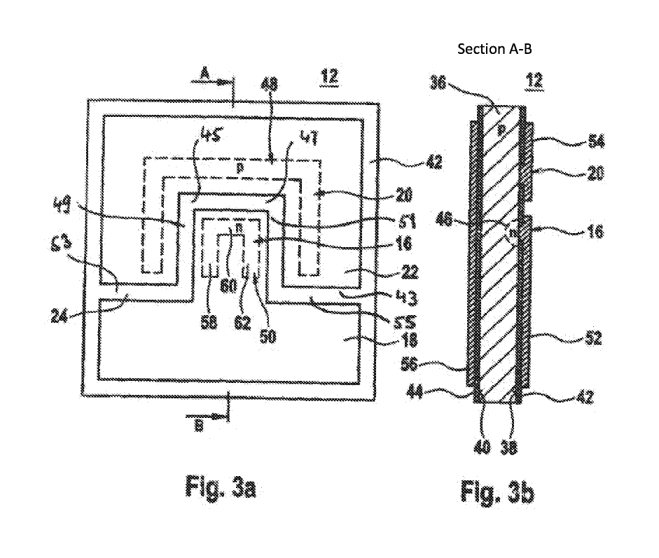

FIG. 3a shows a top view of the carrier substrate with insulation layer and contact windows,

FIG. 3b shows a lateral view of the carrier substrate in a sectional view along the line A-B with metallization, insulation layers and built-in protective diode,

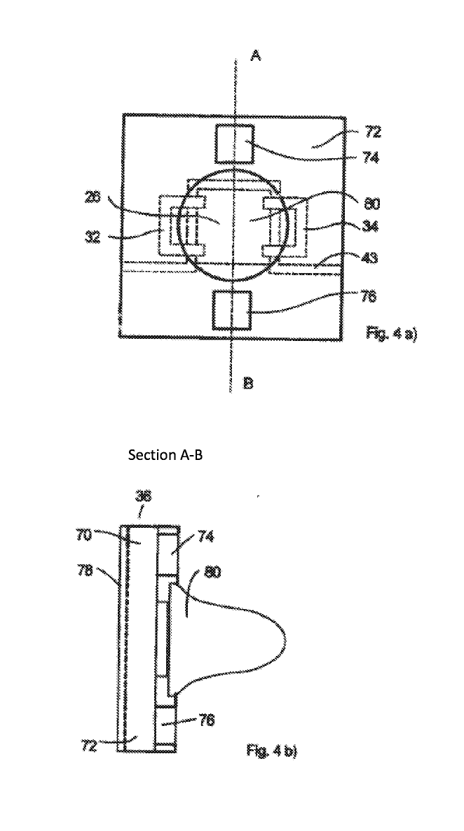

FIG. 4a shows a top view of the photovoltaic assembly in accordance with FIG. 2a with partial jacketing, and

FIG. 4b shows a section along the line A-B in FIG. 4a.

FIG. 1 as well as FIGS. 2a) and 2b) show a photovoltaic assembly 10 in a schematic view comprising a carrier substrate 12, preferably consisting of p-conductive silicon, a solar cell comprising a first and a second solar cell contact 28, 30, in particular concentrator solar cell 26 running with the first solar cell contact 28 on a top side of the carrier substrate 12, as well as comprising a pn junction integrated in the carrier substrate 12 for forming a protective diode 14 with a first protective diode contact 16 and a second protective diode contact 20 connected in antiparallel with the solar cell 26.

The first and second protective diode contacts 16, 20 form a first and a second surface area 18, 22 of the top side 38 of the carrier substrate 12.

FIG. 2a shows a top view of the photovoltaic assembly 10, whereby the solar cell 26 rests with the first solar cell contact 28 (back side contact) on the first surface area 18 and is conductively connected to the latter. The second solar cell contact 30 (front side contact) is connected as soldered via electrical connectors 32, 34 to the second surface area 22 and the second protective diode contact 20.

FIG. 3a) shows a schematic top view and FIG. 3b) shows a schematic sectional view along section line A-B of the carrier substrate 12. The carrier substrate 12 consists of p-conductive, doped silicon 36 whose top side 38 and back side 40 have insulation layers 42, 44, preferably of silicon oxide. An n-conductive zone 46 is diffused or implanted into the top side 38 of the silicon substrate 36 constructed in a p-conductive manner, which zone forms a pn junction of the protective diode 14 together with the p-conductive substrate.

FIG. 3b) shows that the silicon substrate 36 is constructed to be p-conductive as a whole, while the n-conductive zone 46 diffused into or is implanted in the top side 38.

The first and the second protective diode contact s 16, 20 are designed as a first and a second contact window 48, 50 in the insulation layer 42 of the silicon substrate 36, whereby the first protective diode contact 16 is designed as an n-conductive contact and the second protective diode contact 20 as a p-conductive contact.

In order to achieve the greatest possible large-area contacting with the first and second contacts 28, 30 of the solar cell 26, it is provided that the first and the second surface areas 18, 22 have metallizations 52, 54 that are conductively connected to the first and the second contact windows 48, 50.

The metallizations 52, 54 form the contact surfaces on the one hand for the first solar cell contact 28 and on the other hand for the second solar cell contact 30 and the connectors 32, 34.

Furthermore, a back side metallization 56 can be provided on the back side 40 of the silicon substrate 36 in order to make possible a soldered connection of the carrier substrate 12 to another carrier (not shown).

The protective diode 14 is connected in reverse polarity to the solar cell 26.

In order to achieve the greatest possible surface support for the first solar cell contact 28 (bottom side contact), it is provided that the pn junction 46 is designed to be U-shaped, comprising side shanks 58, 62 and transverse shanks 60 that limit the solar cell 26 substantially on its edges, and the insulating layer 24 separating the first and the second surface areas 18, 22 and the metallizations 52, 54 surrounds a contour of the solar cell 26.

Consequently, it can be recognized that the first and the second metallizations 52, 54 extend in a planar manner over the insulation layer 42 running along the top side 38, whereby there is a spacing to the circumferential edge of the substrate 36, as is illustrated in particular in FIGS. 3a and 3b.

The planar metallizations 52, 54 contacted with the U-shaped contact windows 48, 50 nested in one another have on the one hand a U shape (metallization 54 of the p-conductive contact 20) or a T shape (metallization 52 of the n-conductive contact 16), whereby the U shape and the T shape supplement one another, i.e., the middle shank of the T shape extends inside the area surrounded by the shanks of the U shape. The metallizations 52, 54 are separated by a strip-shaped section 43 of the insulation layer 42, as illustrated by the top view according to FIG. 3a. The strip-shaped section 43 comprises a middle section 45 running in the middle area of the substrate 36 and comprising a transverse shank 47 and side shanks 49 and 51. Laterally projecting end sections 53, 55 running parallel to the transverse shank 47 run from the free ends of the side shank 49.

Then, the perforation, that also has a U shape, or the n-conductive contact 16 and outside of the middle section 45 the p-conductive contact of the protective diode 14 extend inside the section 45.

The solar cell 26 is then surrounded by the transverse- and side shanks 47, 49, 51 of the middle section 45, as follows from the drawing view of FIG. 2a.

Furthermore, it can be recognized that the solar cell 28 is arranged in the middle area on the substrate 12.

The invention has the advantage over the prior art, in addition to the integration of the protective diode 14 into the carrier substrate 12, that the first and the second protective diode contacts 16, 20 form surface areas 18, 22 of the carrier substrate 12, so that the solar cell 26 can be mounted in a simple manner At the same time, the carrier substrate serves as a heat sink, protective diode and carrier or plate bar.

There is also the possibility of manufacturing several photovoltaic assemblies 10 on a large semiconductor disk in order to increase the usefulness.

A secondary optical device can be mounted on the solar cell 26.

A corresponding embodiment of the teaching of the invention will be explained in principle using the FIG. 4a and FIG. 4b. Thus, a photovoltaic assembly 70 is shown in the FIGS. 4a, 4b that consists according to the exemplary embodiment of the FIGS. 1 to 3b of the silicon substrate 12 with non-characterized protective diode and protective diode contacts. The solar cell 26 is arranged in the middle area—as in the exemplary embodiment of FIGS. 1 to 3b—whereby the back side contact extends in a planar manner on the metallization surface 52 covering the surface area 18 of the substrate. Reference is made to this extent to the previously made comments. It can also be recognized from the top view of FIG. 4a that the solar cell 26 is connected to the planar metallization area 54 via connectors 32, 34, whereby the metallization areas 52, 54 are electrically insulated from each other by the strip-shaped section 43 of the insulation layer 42.

As a deviation from the exemplary embodiment of FIGS. 1 to 3b the photovoltaic assembly 70 is surrounded by a jacketing 72 extending along the top side and at least in sections along the circumferential sides of the substrate 12. The jacketing can be manufactured by injection molding or the molding of heat-resistant plastic. In the area of the solar cell 26 the jacketing 72 is recessed in order to place an optical element such as a lens, glass body or cover glass on the top side of the solar cell 26 and to be preferably adhered to the latter.

Furthermore, perforations such as windows 74, 76 are present in the area of the metallizations 52, 54 in order to make a connecting of the solar cell 26 possible. An electrically conductive connection can be formed with the p-side contact of the solar cell 26 via the window 74 that exposes the metallization surface 54 in areas with the n-side contact of the solar cell 26 and with the window 76 that exposes the metallization surface 52 in areas.

The jacketing 72 is also present along the bottom side 78 of the silicon carrier 36 in order to make heat dissipation possible.

1. A photovoltaic assembly (10, 70) comprising
a carrier substrate (12) of silicon,
a solar cell (26) comprising a first and a second solar cell contact (28, 30), in particular a concentrator solar cell, which solar cell is connected to the first solar cell contact (28) on a top side (38) of the carrier substrate (12),
a pn junction (46) integrated in the carrier substrate (12) for forming a protective diode (14) with a first protective diode contact (16) and with a second protective diode contact (20) connected in antiparallel to the solar cell (26), whereby the first and the second protective diode contacts (16, 20) respectively form a first and a second surface area (18, 22) of the top side (38) of the carrier substrate (12), characterized in that
the top side (38) of the carrier substrate (12) is provided with an insulation layer (42), whereby a first contact window (50) for the first protective diode contact (16) is formed in the first surface area (18) and in the second surface area (22) a second contact window (48) for the second protective diode contact (20) is formed, that the first surface area (18) comprises a first metallization (52) conductively connected to the first contact window (50) and that the second surface area (22) comprises a second metallization (54) connected to the second contact window (48),
that the first and the second metallizations are constructed as the first and the second metallization surfaces, and that the solar cell (26) lies with the first solar cell contact (28) in a planar manner on the first metallization surface and that the second solar cell contact (30) is connected via connectors (34, 32) to the second metallization surface.

2. The photovoltaic assembly according to claim 1,
characterized in that
the metallization surfaces (52, 54) run in a plane.

3. The photovoltaic assembly according to claim 1,
characterized in that
the first protective diode contact (16) in the form of an n- or p-conductive zone (46) as the first surface area (18) diffuses into the top side (38) of the p- or n-conductive carrier substrate (12), consisting especially of silicon, which top side forms the second surface area (22), or this contact is implanted and has a U-shaped course.

4. The photovoltaic assembly according to claim 1,
characterized in that
the n- or p-conductive zone (46) limits a surface that corresponds to a contact surface or substantially to a contact surface of the first solar cell contact (28).

5. The photovoltaic assembly according to previous claim 1,
characterized in that
the solar cell (26) covers an area of the first metallization surface (52) that extends inside the second metallization surface (54).

6. The photovoltaic assembly according to claim 1,
characterized in that
the carrier substrate (12) comprises a back side insulation layer (44) such as a silicon oxide layer and/or a back side metallization (56).

7. The photovoltaic assembly according to claim 1,
characterized in that
the solar cell (26) is a CPV concentrator solar cell.

8. The photovoltaic assembly according to claim 1,
characterized in that
the metallization or metallizations (52, 54, 56) form/s a heat sink for at least the solar cell (26), in particular for the protective diode (14) and the solar cell.

9. The photovoltaic assembly according to claim 1,
characterized in that
the solar cell (26) is covered by an optical element (80), in particular it is adhered to the latter.

10. The photovoltaic assembly according to claim 1,
characterized in that
the front side of the carrier substrate (12, 36) and at least in sections its circumferential sides are covered by a jacketing (72) that is recessed at least above the solar cell (26).

11. The photovoltaic assembly according to claim 1,
characterized in that
the jacketing (72) has a recess (74, 76) above the first and the second metallizations (52, 54).

12. The photovoltaic assembly according to claim 1,
characterized in that
the back side (74) of the substrate (12, 36) has no jacketing.

13. The photovoltaic assembly according to claim 1,
characterized in that
the first and the second metallizations (52, 5) are separated in a top view onto the carrier substrate (12, 36) by an insulation section (43) of the insulation layer (42) running in a strip, that the insulation section consists of a middle area of the substrate surrounding the middle section (45) with transverse shanks and side shanks (48, 49, 51) and extending parallel to or approximately parallel to the n- or p-conductive zone (46) running in a U-shape and of outer sections (53, 55)running from the free ends of the side shanks and parallel to the transverse shank, and that the solar cell is surrounded by the middle section or runs inside it.

14. The photovoltaic assembly according to claim 1,
characterized in that a connector (32, 34) emanates at least from two opposite sides of the second solar cell contact (30) that extends over one of the side shanks of the strip-shaped section (43) of the insulation layer (42).
